(19) United States
(12) Patent Application Publication
(10) Pub. No.: US 2010/0134146 A1
(43) Pub. Date: Jun. 3, 2010

(54) VOLTAGE LEVEL TRANSLATOR AND METHOD

(75) Inventor: ONEGYUN NA, Boise, ID (US)

Correspondence Address: DORSEY & WHITNEY LLP;INTELLECTUAL PROPERTY DEPARTMENT, Columbia Center, 701 Fifth Avenue, Suite 6100, SEATTLE, WA, 98104-7043, US

(73) Assignee: Micron Technology, Inc., Boise, ID (US)

(21) Appl. No.: 12/327,472

(22) Filed: Dec. 3, 2008

(51) Int. Cl. H03K 19/0175; H03L 5/00

(52) U.S. Cl. 326/81; 326/80; 327/333

(57) ABSTRACT

A level translator includes an NMOS input transistor and a PMOS input transistor having respective gates receiving an input voltage. The input transistors compare the input voltage to respective first and second supply voltages. The input voltage is also applied to an inverter that is powered by the first and second supply voltages. An output terminal is coupled to a third supply voltage through a PMOS output transistor and to a fourth supply voltage through an NMOS output transistor. The third and fourth supply voltages are outside of a range bounded by the first and second supply voltages. The respective drains of the input transistors and the output of the inverter are coupled to the gates of the output transistors in a manner that either turns the PMOS output transistor ON and the NMOS output transistor OFF or turns the NMOS output transistor ON and the PMOS output transistor OFF.

### TECHNICAL FIELD

This application relates to signal coupling circuits and methods, and, more particularly, to circuits and methods that translate the logic level voltages of an incoming binary signal to at least one other voltage.

### BACKGROUND OF THE INVENTION

A wide variety of circuits are used in integrated circuits, such as memory devices. One type of commonly used circuit is a level translator. A level translator typically receives a binary signal that varies between two logic levels corresponding to respective voltage levels. For example, the binary signal may vary between 0 and 5 volts. In response to the binary input signal, a level translator provides a binary output signal that varies between two voltages, at least one of which is different from the voltage levels to which the logic levels of the input signal correspond. For example, in response to an input signal that switches between 0 and 5 volts, the output signal may be switched between 10 and 0 volts, respectively. Such level translators are typically used as an interface between an electronic circuit operating between two voltage levels and electronic circuitry operating between two voltage levels, at least one of which is different from the voltage levels used by the electronic device. For example, some memory device output buffers drive a bus data terminal using a pair of NMOS transistors coupled in series between a supply voltage and ground. In order for the NMOS transistor connected to the supply voltage to drive the data terminal to the full magnitude of the supply voltage, it is necessary to apply a signal greater than the supply voltage to the gate of the NMOS transistor. Insofar as the remainder of the memory device is powered by the supply voltage, a level translator powered by an elevated voltage can be used to supply a suitable voltage to the gate of the NMOS transistor.

A typical prior art level translator 10 that receives a binary signal switching between 0 and V_{CC} is shown in FIG. 1. The level translator 10 includes an input circuit 12 including a pair of cross-coupled PMOS transistors 14, 16 that have their sources connected to an elevated voltage V_{CCP}. The drain of the PMOS transistor 14 is coupled to ground through an NMOS transistor 20, and the drain of the PMOS transistor 16 is coupled to ground through a second NMOS transistor 22. An input voltage V_{IN} is applied to the gate of the transistor 20 and to an inverter 28, which is powered by ground and the supply voltage V_{CC}. The output of the inverter 28 drives the gate of the NMOS transistor 22.

An output of the input circuit 12 taken at the junction between the transistors 16, 22 is applied to an inverter 30 formed by a PMOS transistor 34 and an NMOS transistor 36. The source of the PMOS transistor 34 is coupled to the elevated voltage V_{CCP}, and the source of the NMOS transistor 36 is coupled to ground.

In operation, an input signal level of V_{CC} turns ON the NMOS transistor 14 and causes the inverter to turn OFF the NMOS transistor 22. The transistor 20 then pulls the gate of the PMOS transistor 16 to ground, thereby turning ON the transistor 16 to apply V_{CCP} to the inverter 30. This voltage turns OFF the PMOS transistor 34 and turns ON the NMOS transistor 36, thereby pulling the output voltage V_{OUT} to ground. Thus, when the input voltage V_{IN} is at V_{CC}, the output voltage V_{OUT} is at ground. When the input voltage V_{IN} is at ground, the transistor 20 is turned OFF, and the inverter 28 outputs V_{CC} to turn ON the transistor 22. The input circuit 12 thus outputs 0 volts, which turns ON the PMOS transistor 34 so that the output voltage is at the elevated voltage V_{CCP}.

Another prior art level translator 40 is shown in FIG. 2. The level translator 40 has essentially the same typography as the level translator 10 shown in FIG. 1 except that it uses cross-coupled NMOS transistors 44, 46 in place of the cross-coupled PMOS transistors 14, 16, and it uses PMOS transistors 50, 52 receiving complimentary voltages generated by an inverter 58 in place of the NMOS transistors 20, 22.

The level translator 40 operates in essentially the same manner as the level translator 10. An input voltage V_{IN} of 0 volts turns ON the PMOS transistor 52 to couple the supply voltage V_{CC} to the gate of the NMOS transistor 46. The NMOS transistor 46 is thus turned ON so that it drives the output voltage V_{OUT} to a negative supply voltage V_{NN}. An input voltage V_{IN} equal to the supply voltage V_{CC} turns OFF the PMOS transistor 50 and causes the inverter 58 to turn ON the PMOS transistor 52, thereby coupling the output voltage V_{OUT} to V_{CC}. Therefore, in response to the input voltage V_{IN} switching between 0 volts and V_{CC}, the output voltage V_{OUT} switches between V_{NN} and V_{CC}.

Although the level translators 10, 40, as well as other prior art level translators, can be used to alter the voltage level corresponding to the logic levels of the input signal, they cannot alter the voltage levels corresponding to both logic levels of the input signal to respective voltages that are both outside a range of voltages bounded by the two voltages corresponding to the logic levels of the input signal. For example, if the level translator 10 was powered by a negative voltage rather than ground, the transistor 20 would not turn OFF when the input voltage V_{IN} was at 0 volts.

There is therefore a need for a level translator and method that can translate voltages corresponding to two logic levels of an input signal to respective voltages that are both outside a range of voltages bounded by the two voltages corresponding to the logic level of the input signal.

### BRIEF DESCRIPTION OF THE DRAWINGS

FIG. 1 is a schematic diagram of a prior art level translator.

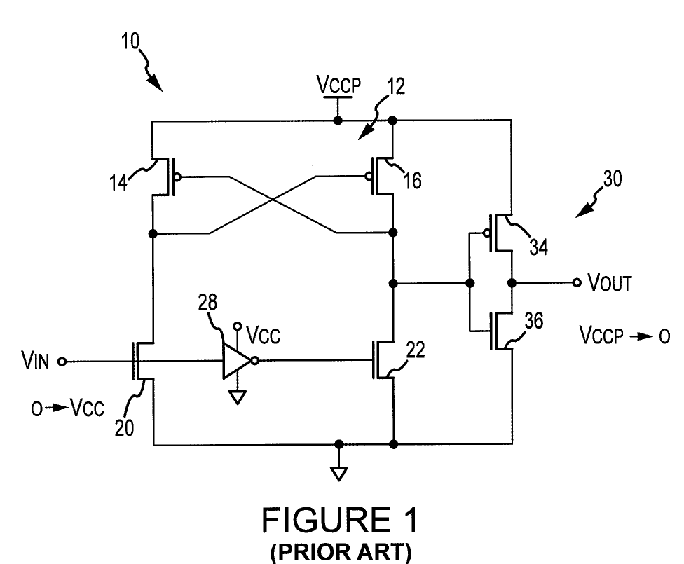

FIG. 2 is a schematic diagram of another prior art level translator.

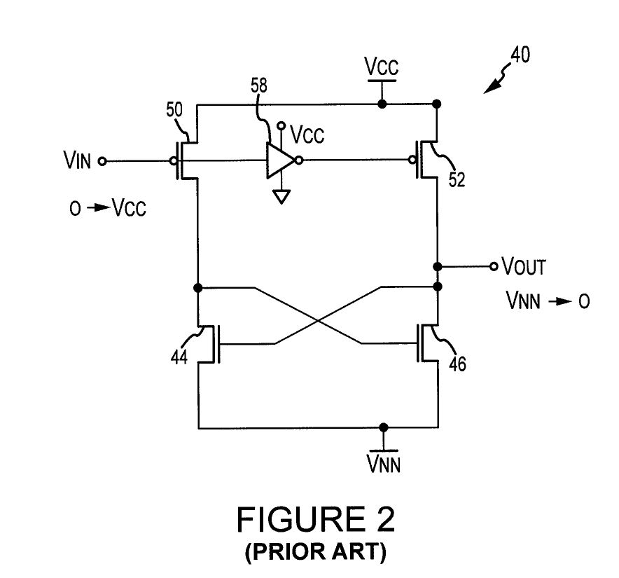

FIG. 3 is a block diagram of a level translator according to an embodiment of the invention.

FIG. 4 is a schematic diagram of a level translator according to an embodiment of the invention.

FIG. 5 is a schematic diagram of a level translator according to another embodiment of the invention.

### DETAILED DESCRIPTION

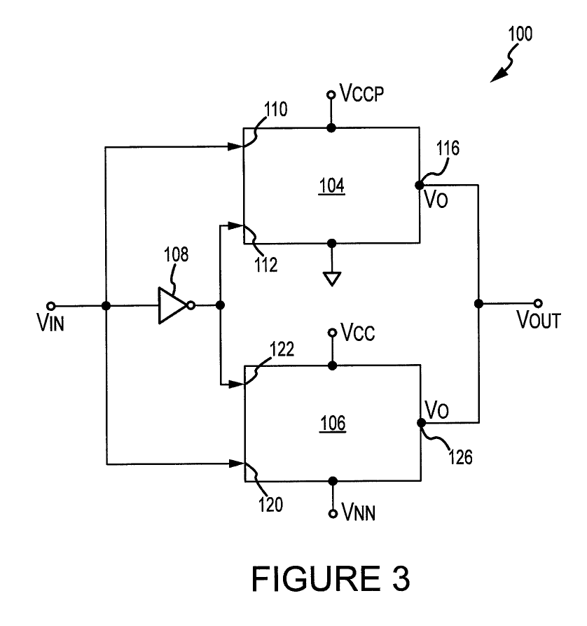

A level translator 100 according to an embodiment of the invention is shown in FIG. 3. The level translator 100 includes two level translator circuits 104, 106 and an inverter 108, which receives an input signal V_{IN}. The level translator circuit 104 also receives the input signal V_{IN} at an input terminal 110 and the output of the inverter 108 at an input terminal 112. In response to the input signal V_{IN}, the level translator circuit 104 provides an output signal V_{O} at an output terminal 116. The level translator circuit 104 is powered by an elevated supply voltage V_{CCP} and ground. In response to an input voltage V_{IN} of V_{CC}, the level translator circuit 104 provides an output voltage V_{O} equal to the elevated supply voltage V_{CCP}. In response to an input voltage V_{IN} of 0 volts, the inverter 108 applies a voltage of V_{CC} to the input terminal 112 of the level translator circuit 104, which causes the level translator circuit 106 to tri-state the output terminal 116 to a high impedance.

The level translator 100 also includes a second level translator circuit 106 that also receives the input voltage V_{IN} at an input terminal 120 and the output of the inverter 108 at an input terminal 122. In response to the input signal V_{IN}, the level translator circuit 106 provides an output signal V_{O} at an output terminal 126. The output terminal 126 is connected to the output terminal 116 of the first level translator circuit 104. The level translator circuit 106 is powered by the supply voltage V_{CC} and a negative elevated supply voltage V_{NN}. In response to an input voltage V_{IN} of V_{CC}, the inverter 108 applies a 0 volt signal to the input terminal 122 of the level translator circuit 106 that causes it to tri-state the output terminal 126 to a high impedance. In response to an input voltage V_{IN} of 0 volts, the level translator circuit 106 provides an output voltage V_{O} equal to the negative elevated supply voltage V_{NN}. Therefore, the level translator 100 responds to input voltages V_{IN} of 0 volts and the supply voltage V_{CC} by providing output voltages V_{OUT} equal to the negative elevated supply voltage V_{NN} and the positive elevated voltage V_{CCP}, respectively. The magnitudes of the output voltages can have absolute values that are greater than the absolute values of the input voltages so that they are outside a range of voltages bounded by 0 volts and V_{CC}.

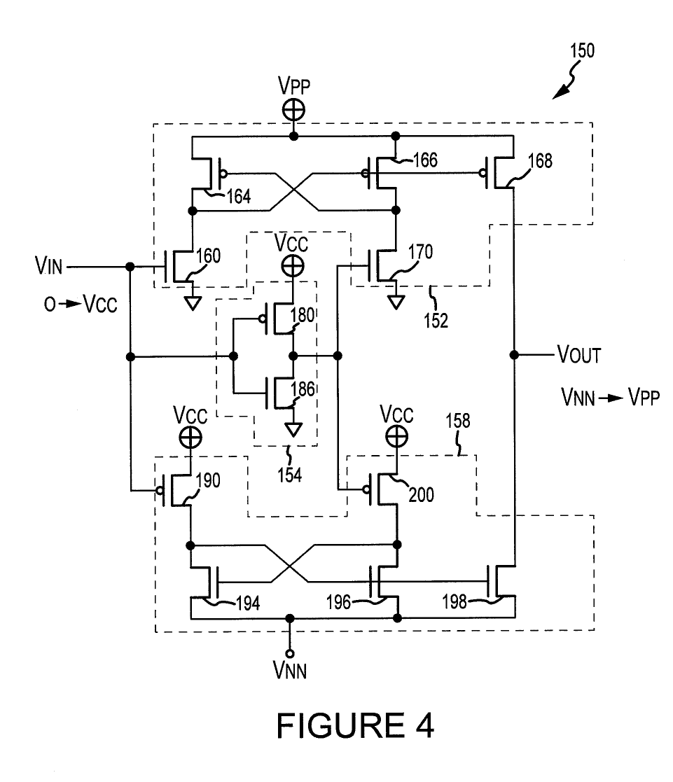

A level translator 150 according to another embodiment of the invention is shown in FIG. 4. The level translator 150, like the level translator 100, includes a level translating circuit 152 powered by an elevated supply voltage V_{PP} and ground, an inverter 154 and a level translating circuit 158 powered by a supply voltage V_{CC} and a negative elevated supply voltage V_{NN}. The level translating circuit 152 includes an NMOS transistor 160 receiving the input voltage V_{IN} at its gate, a pair of cross-coupled PMOS transistors 164, 166 having their sources coupled to the elevated supply voltage V_{PP}, an output PMOS output transistor 168 and an NMOS transistor 170 having its gate connected to the output of the inverter 154, which is formed by a PMOS transistor 180 and an NMOS transistor 186. Similarly, the level translating circuit 158 includes a PMOS transistor 190 receiving the input voltage V_{IN} at its gate, a pair of cross-coupled NMOS transistors 194, 196 having their sources coupled to the negative elevated supply voltage V_{NN}, an output NMOS output transistor 198 and a PMOS transistor 200 having its gate connected to the output of the inverter 154.

In operation, an input voltage V_{IN} of 0 volts turns OFF the NMOS transistor 160 and turns ON the PMOS transistor 190. The PMOS transistor 190 therefore couples the supply voltage V_{CC} to the gate of the NMOS output transistor 198. The transistor 198 then turns ON to drive the output voltage V_{OUT} to the negative elevated supply voltage V_{NN}. At the same time, the 0 volt input voltage V_{IN} causes the inverter 154 to apply the supply voltage V_{CC} to the gate of the NMOS transistor 170 in the voltage translating circuit 152. As a result, the PMOS transistor 164 is turned ON to apply the elevated supply voltage V_{PP} to the gates of the PMOS output transistors 166, 168 thereby turning OFF the transistors 166, 168.

An input voltage V_{IN} of V_{CC} turns ON the NMOS transistor 160 and turns OFF the PMOS transistor 190. As a result, the gates of the PMOS transistors 166, 168 are coupled to ground thereby turning ON the transistors 166, 168. The PMOS transistor 166 then turns OFF the PMOS transistor 164, and the PMOS transistor 168 drives the output voltage V_{OUT} to the elevated supply voltage V_{PP}. At the same time, the input voltage V_{IN} of V_{CC} causes the inverter 154 to turn ON the PMOS transistor 200 in the voltage translating circuit 158. As a result, the NMOS transistor 194 is turned ON to couple to the gates of the NMOS transistors 196, 198 to V_{NN}, thereby turning OFF the output transistors 196, 198.

In summary, the NMOS transistor 160 is responsible for turning ON the PMOS output transistor 168 to drive the output signal V_{OUT} to V_{PP}, and the PMOS transistor 190 is similarly responsible for turning ON the NMOS output transistor 198 to drive the output signal V_{OUT} to V_{NN}. The inverter 154 and the NMOS transistor 170 are responsible for ti-stating the output transistor 168 when V_{OUT} is at V_{NN}, and the inverter 154 and the PMOS transistor 160 are responsible for tri-stating the output transistor 198 when V_{OUT} is at V_{PP}.

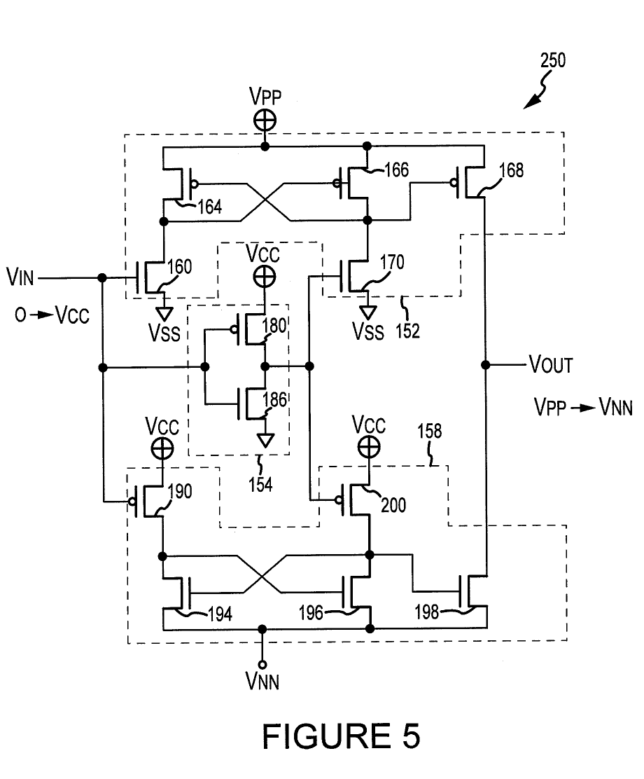

A level translator 250 according to another embodiment of the invention is shown in FIG. 5. The level translator 250 uses the same components that are used in the level translator 150 of FIG. 4. Therefore, like components have been provided with the same reference numeral. However, the level translator 250 has a different topography. Specifically, the gate of the PMOS output transistor 168 is coupled to the drain of the PMOS transistor 166 rather than to the gate of the PMOS transistor 166. Similarly, the gate of the NMOS output transistor 198 is coupled to the drain of the NMOS transistor 196 rather than to the gate of the NMOS transistor 196. While this difference in topography is relatively slight, it causes the level translator 250 to operate in a substantially different manner from the level translator 150 shown in FIG. 4. Specifically, while the level translator 150 does not invert the voltage V_{IN} applied to the input of the level translator 150, the level translator 250 does invert the voltage V_{IN} applied to its input.

In operation, an input voltage V_{IN} of 0 volts turns ON the PMOS transistor 190 as explained above. However, the voltage V_{CC} coupled through the PMOS transistor 190 does not turn ON the NMOS transistor 198 as in the level translator 150. Instead, it again turns ON the NMOS transistor 196, but doing so causes the transistor 196 to turn OFF the NMOS output transistor 198. The input voltage V_{IN} of 0 volts also causes the inverter 154 to turn ON the NMOS transistor 170, which, in turn, turns ON the PMOS output transistor 168. Therefore, an input voltage V_{IN} of 0 volts causes the level translator 250 to generate an output voltage V_{OUT} of V_{PP}.

The level translator 250 responds in a complementary manner to an input voltage V_{IN} equal to V_{CC}. The input voltage V_{IN} of V_{CC} turns ON the NMOS transistor 160 which, rather than turning ON the PMOS output transistor 168 as in the level translator 150, simply causes the PMOS transistor 166 to turn OFF the PMOS transistor 164. The input voltage V_{IN} of V_{CC} also causes the inverter 154 to output a voltage of 0 volts, which turns ON the PMOS transistor 200 to apply the voltage V_{CC} to the gate of the NMOS output transistor 198, thereby generating an output voltage V_{OUT} of V_{NN}. Therefore, an input voltage V_{IN} of V_{CC} causes the level translator 250 generate an output voltage V_{OUT} of V_{NN}.

The difference between the operation of the level translator 250 and the operation of the level translator 150 is more than simply inverting the input voltage V_{IN}. Specifically, in the level translator 150, the inverter 154 is responsible for tri-stating the output transistors 168, 198, as explained above. However, in the level translator 250, the inverter 154 is responsible for alternately turning ON the output transistors 168, 198 to drive the output voltage V_{OUT} to either V_{PP} or V_{NN}. In the level translator 250, the function of tri-stating the output transistors 168, 198 is performed by the NMOS input transistor 160 along with the PMOS transistors 164, 166, and the PMOS input transistor 190 along with the NMOS transistors 194, 196.

In summary, the NMOS transistor 160 is responsible for turning ON the PMOS output transistor 168 to drive the output signal V_{OUT} to V_{PP}, and the PMOS transistor 190 is similarly responsible for turning ON the NMOS output transistor 198 to drive the output signal V_{OUT} to V_{NN}. The inverter 154 and the NMOS transistor 170 are responsible for tri-stating the output transistor 168 when V_{OUT} is at V_{NN}, and the inverter 154 and the PMOS transistor 160 are responsible for tri-stating the output transistor 198 when V_{OUT is at V}_{PP}.

Although the present invention has been described with reference to the disclosed embodiments, persons skilled in the art will recognize that changes may be made in form and detail without departing from the invention. Such modifications are well within the skill of those ordinarily skilled in the art. Accordingly, the invention is not limited except as by the appended claims.

1. A level translator, comprising:
an inverter coupled to receive a binary input signal having first and second logic levels corresponding to first and second voltages, respectively;
a first level translating circuit having a first input coupled to receive the input signal and a second input coupled to an output of the inverter, the first level translating circuit being responsive to the input signal to couple a third voltage to an output node responsive to the input signal being one of the first logic level and the second logic level, and to place the output node at a high impedance responsive to the input signal being the other of the first logic level and the second logic level, the third voltage being outside a range of voltages bounded by the first and second voltages the first level translating circuit comprising:
an NMOS input transistor having a gate coupled to receive the input signal, a source coupled to a supply voltage having a magnitude equal to one of the first voltage and the second voltage, and a drain;
a first PMOS transistor having a drain coupled to the drain of the NMOS input transistor, a source coupled to a supply voltage having a magnitude equal to the third voltage, and a gate;
a second PMOS transistor having a drain coupled to the gate of the first PMOS transistor, a gate coupled to the drain of the first PMOS transistor, a source coupled to the supply voltage having a magnitude equal to the third voltage; and
a PMOS output transistor having a source coupled to the supply voltage having a magnitude equal to the third voltage, a gate coupled to the gate of the second PMOS transistor, and a drain coupled to the output node of the first level translating circuit; and
a second level translating circuit having a first input coupled to receive the input signal and a second input coupled to the output of the inverter, the second level translating circuit being responsive to the input signal to couple a fourth voltage to an output node responsive to the input signal being the other of the first logic level and the second logic level, and to place the output node at a high impedance responsive to the input signal being the one of the first logic level and the second logic level, the fourth voltage being different from the third voltage and being outside the range of voltages bounded by the first and second voltages.

2-7. (canceled)

8. The level translator of 1 wherein the first level translating circuit further comprises a first NMOS transistor having a gate coupled to the output of the inverter, a source coupled to the supply voltage having a magnitude equal to one of the first voltage and the second voltage, and a drain coupled to the drain of the second PMOS transistor.

9. The level translator of claim 1 wherein the second level translating circuit comprises:
a PMOS input transistor having a gate coupled to receive the input signal, a source coupled to a supply voltage having a magnitude equal to other of the first voltage and the second voltage, and a drain;
a first NMOS transistor having a drain coupled to the source of the PMOS input transistor, a source coupled to a supply voltage having a magnitude equal to the fourth voltage, and a gate;
a second NMOS transistor having a drain coupled to the gate of the first NMOS transistor, a gate coupled to the drain of the first NMOS transistor, and a source coupled to the supply voltage having a magnitude equal to the fourth voltage; and
an NMOS output transistor having a source coupled to the supply voltage having a magnitude equal to the fourth voltage, a gate coupled to the second NMOS transistor, and a drain coupled to the output node of the second level translating circuit.

10-25. (canceled)

26. The level translator of claim 1 wherein the output node of the first level translating circuit is connected to the output node of the second level translating circuit.

27. A level translator, comprising:
an inverter coupled to receive a binary input signal having first and second logic levels corresponding to first and second voltages, respectively;
a first level translating circuit having a first input coupled to receive the input signal and a second input coupled to an output of the inverter, the first level translating circuit being responsive to the input signal to couple a third voltage to an output node responsive to the input signal being one of the first logic level and the second logic level, and to place the output node at a high impedance responsive to the input signal being the other of the first logic level and the second logic level, the third voltage being outside a range of voltages bounded by the first and second voltages; and
a second level translating circuit having a first input coupled to receive the input signal and a second input coupled to the output of the inverter, the second level translating circuit being responsive to the input signal to couple a fourth voltage to an output node responsive to the input signal being the other of the first logic level and the second logic level, and to place the output node at a high impedance responsive to the input signal being the one of the first logic level and the second logic level, the fourth voltage being different from the third voltage and being outside the range of voltages bounded by the first and second voltages, the second level translating circuit comprising:
a PMOS input transistor having a gate coupled to receive the input signal, a source coupled to a supply voltage having a magnitude equal to other of the first voltage and the second voltage, and a drain;
a first NMOS transistor having a drain coupled to the source of the PMOS input transistor, a source coupled to a supply voltage having a magnitude equal to the fourth voltage, and a gate;
a second NMOS transistor having a drain coupled to the gate of the first NMOS transistor, a gate coupled to the drain of the first NMOS transistor, and a source coupled to the supply voltage having a magnitude equal to the fourth voltage; and
an NMOS output transistor having a source coupled to the supply voltage having a magnitude equal to the fourth voltage, a gate coupled to the gate of the second NMOS transistor, and a drain coupled to the output node of the second level translating circuit.

28. The level translator of 27 wherein the second level translating circuit further comprises a first PMOS transistor having a gate coupled to the output of the inverter, a source coupled to the supply voltage having a magnitude equal to one of the first voltage and the second voltage, and a drain coupled to the drain of the second NMOS transistor.
